(19) United States
(12) Patent Application Publication
(10) Pub. No.: US 2026/0181834 A1
(43) Pub. Date: Jun. 25, 2026

(54) COUNTER-FLOW HEATSINK FOR SERVER PROCESSOR

(71) Applicant: Lenovo Global Technology (United States) Inc., Morrisville, NC (US)

(72) Inventor: Shreekanth Murthy Muthigi, Karnataka (IN)

(21) Appl. No.: 18/988,125

(22) Filed: Dec. 19, 2024

(51) Int. Cl. H05K 7/20

(52) U.S. Cl. CPC H05K 7/20736; H05K 7/20145; H05K 7/20154; H05K 7/20172; H05K 7/20409; H05K 7/20836

(57) ABSTRACT

An apparatus with counter-flow cooling tubes includes a cooling tube configured to sit within a first portion of a slot between first and second fins of a heat sink of a computing device, where the heat sink is thermally coupled to one or more components of the computing device. The cooling tube is configured to have sides of the cooling tube contact sides of the slot. The apparatus includes one or more fans configured to direct air in a first direction through a second portion of the slot, and an air source coupled to the cooling tube configured to direct air through the cooling tube in a second direction opposite the first direction.

### FIELD

The subject matter disclosed herein relates to cooling of a computing device and more particularly relates to using counter-flow cooling tubes to supplement airflow cooling of a computing device.

### BACKGROUND

Today's existing generation of a one unit (“1U”) server includes air cooling that can support 250 watts (“W”) with an enhances vapor chamber (“EVAC”) heatsink and can support 300 W at a lower ambient (25° C.) temperature. The next generation server processor has a thermal design power (“TDP”) that is 600 W and expected to reach 1000 W. Air cooling configurations in 1U servers can not extend central processing unit (“CPU”) TDP support to 600 W.

### BRIEF SUMMARY

An apparatus with counter-flow cooling tubes includes a cooling tube configured to sit within a first portion of a slot between first and second fins of a heat sink of a computing device, where the heat sink is thermally coupled to one or more components of the computing device. The cooling tube is configured to have sides of the cooling tube contact sides of the slot. The apparatus includes one or more fans configured to direct air in a first direction through a second portion of the slot, and an air source coupled to the cooling tube configured to direct air through the cooling tube in a second direction opposite the first direction.

An apparatus for using a computing device with counter-flow cooling tubes includes a cooling tube configured to sit within a first portion of a slot between a first electronic component and a second electronic component of a computing device. The cooling tube is configured to contact both the first and second electronic component. The apparatus includes one or more fans configured to direct air in a first direction through a second portion of the slot, and an air source coupled to the cooling tube and configured to direct air through the cooling tube in a second direction opposite the first direction.

A system for a computing device with counter-flow cooling tubes includes a computing device that includes a chassis, a processor in the chassis, one or more memory cards in the chassis in communication with the processor, and a cooling tube configured to fill a first portion of a slot between fins of a heat sink thermally coupled to one or more components of the computing device, or a slot between at least two components of the computing device. The processor and the one or more memory cards are included as components of the computing device. The computing device includes one or more fans configured to direct air in a first direction through a second portion of the slot. The system includes an air source coupled to the cooling tube configured to direct air through the cooling tube in a second direction opposite the first direction.

### BRIEF DESCRIPTION OF THE DRAWINGS

A more particular description of the embodiments briefly described above will be rendered by reference to specific embodiments that are illustrated in the appended drawings. Understanding that these drawings depict only some embodiments and are not therefore to be considered to be limiting of scope, the embodiments will be described and explained with additional specificity and detail through the use of the accompanying drawings, in which:

FIG. 1 is a schematic block diagram illustrating a dual server with heat sinks over processors with counter-flow cooling tubes in slots of the heat sinks, according to various embodiments;

FIG. 2 is a schematic block diagram illustrating a dual server with counter-flow cooling tubes extending through slots between memory cards, according to various embodiments;

FIG. 3 is a schematic block diagram illustrating a dimensional view of heat sink, according to various embodiments;

FIG. 4 is a schematic block diagram illustrating a dimensional view of a heat sink with counter-flow cooling tubes in slots of the heat sink, according to various embodiments;

FIG. 5A is a schematic block diagram illustrating a heat sink with counter-flow cooling tubes positioned at the bottom of slots in the heat sink, according to various embodiments;

FIG. 5B is a schematic block diagram illustrating a heat sink with counter-flow cooling tubes positioned at the top of slots in the heat sink, according to various embodiments;

FIG. 5C is a schematic block diagram illustrating a heat sink with counter-flow cooling tubes positioned at the top and the bottom of slots in the heat sink, according to various embodiments;

FIG. 6A is a schematic block diagram illustrating a side section view of a heat sink with a counter-flow cooling tube curved to avoid heat tubes, according to various embodiments;

FIG. 6B is a schematic block diagram illustrating a side section view of another heat sink with a counter-flow cooling tube curved to avoid heat tubes, according to various embodiments;

FIG. 7 is a Table I illustrating different cooling tube designs and air flow rates, according to various embodiments;

FIG. 8 is a schematic block diagram illustrating a dual server with heat sinks over processors with counter-flow cooling tubes in slots of the heat sinks with temperature sensors and an air flow controller, according to various embodiments; and

FIG. 9 is a schematic block diagram illustrating a dual server with heat sinks over processors with counter-flow cooling tubes in slots of the heat sinks and fans providing air for the cooling tubes, according to various embodiments.

### DETAILED DESCRIPTION

As will be appreciated by one skilled in the art, aspects of the embodiments may be embodied as a system, method or program product. Accordingly, embodiments may take the form of an entirely hardware embodiment, an entirely software embodiment (including firmware, resident software, micro-code, etc.) or an embodiment combining software and hardware aspects that may all generally be referred to herein as a “controller,” “circuit,” “module” or “system.” Furthermore, embodiments may take the form of a program product embodied in one or more computer readable storage devices storing machine readable code, computer readable code, and/or program code, referred hereafter as code. The storage devices, in some embodiments, are tangible, non-transitory, and/or non-transmission.

Many of the functional units described in this specification have been labeled as controllers, in order to more particularly emphasize their implementation independence. For example, a controller may be implemented as a hardware circuit comprising custom very large scale integrated (“VLSI”) circuits or gate arrays, off-the-shelf semiconductors such as logic chips, transistors, or other discrete components. A controller may also be implemented in programmable hardware devices such as a field programmable gate array (“FPGA”), programmable array logic, programmable logic devices or the like.

Controllers may also be implemented in code and/or software for execution by various types of processors. An identified controller of code may, for instance, comprise one or more physical or logical blocks of executable code which may, for instance, be organized as an object, procedure, or function. Nevertheless, the executables of an identified controller need not be physically located together, but may comprise disparate instructions stored in different locations which, when joined logically together, comprise the controller and achieve the stated purpose for the controller.

Indeed, a controller of code may be a single instruction, or many instructions, and may even be distributed over several different code segments, among different programs, and across several memory devices. Similarly, operational data may be identified and illustrated herein within controllers, and may be embodied in any suitable form and organized within any suitable type of data structure. The operational data may be collected as a single data set, or may be distributed over different locations including over different computer readable storage devices. Where a controller or portions of a controller are implemented in software, the software portions are stored on one or more computer readable storage devices.

Any combination of one or more computer readable medium may be utilized. The computer readable medium may be a computer readable storage medium. The computer readable storage medium may be a storage device storing the code. The storage device may be, for example, but not limited to, an electronic, magnetic, optical, electromagnetic, infrared, holographic, micromechanical, or semiconductor system, apparatus, or device, or any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

More specific examples (a non-exhaustive list) of the storage device would include the following: an electrical connection having one or more wires, a portable computer diskette, a hard disk, a random access memory (“RAM”), a read-only memory (“ROM”), an erasable programmable read-only memory (“EPROM” or Flash memory), a portable compact disc read-only memory (“CD-ROM”), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Code for carrying out operations for embodiments may be written in any combination of one or more programming languages including an object oriented programming language such as Python, Ruby, R, Java, Java Script, Smalltalk, C++, C sharp, Lisp, Clojure, PHP, or the like, and conventional procedural programming languages, such as the “C” programming language, or the like, and/or machine languages such as assembly languages. The code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (“LAN”) or a wide area network (“WAN”), or the connection may be made to an external computer (for example, through the Internet using an Internet Service Provider).

Reference throughout this specification to “one embodiment,” “an embodiment,” or similar language means that a particular feature, structure, or characteristic described in connection with the embodiment is included in at least one embodiment. Thus, appearances of the phrases “in one embodiment,” “in an embodiment,” and similar language throughout this specification may, but do not necessarily, all refer to the same embodiment, but mean “one or more but not all embodiments” unless expressly specified otherwise. The terms “including,” “comprising,” “having,” and variations thereof mean “including but not limited to,” unless expressly specified otherwise. An enumerated listing of items does not imply that any or all of the items are mutually exclusive, unless expressly specified otherwise. The terms “a,” “an,” and “the” also refer to “one or more” unless expressly specified otherwise.

Furthermore, the described features, structures, or characteristics of the embodiments may be combined in any suitable manner. In the following description, numerous specific details are provided, such as examples of programming, software controllers, user selections, network transactions, database queries, database structures, hardware controllers, hardware circuits, hardware chips, etc., to provide a thorough understanding of embodiments. One skilled in the relevant art will recognize, however, that embodiments may be practiced without one or more of the specific details, or with other methods, components, materials, and so forth. In other instances, well-known structures, materials, or operations are not shown or described in detail to avoid obscuring aspects of an embodiment.

Aspects of the embodiments are described below with reference to schematic flowchart diagrams and/or schematic block diagrams of methods, apparatuses, systems, and program products according to embodiments. It will be understood that each block of the schematic flowchart diagrams and/or schematic block diagrams, and combinations of blocks in the schematic flowchart diagrams and/or schematic block diagrams, can be implemented by code. This code may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the schematic flowchart diagrams and/or schematic block diagrams block or blocks.

The code may also be stored in a storage device that can direct a computer, other programmable data processing apparatus, or other devices to function in a particular manner, such that the instructions stored in the storage device produce an article of manufacture including instructions which implement the function/act specified in the schematic flowchart diagrams and/or schematic block diagrams block or blocks.

The code may also be loaded onto a computer, other programmable data processing apparatus, or other devices to cause a series of operational steps to be performed on the computer, other programmable apparatus or other devices to produce a computer implemented process such that the code which execute on the computer or other programmable apparatus provide processes for implementing the functions/acts specified in the flowchart and/or block diagram block or blocks.

The schematic flowchart diagrams and/or schematic block diagrams in the Figures illustrate the architecture, functionality, and operation of possible implementations of apparatuses, systems, methods and program products according to various embodiments. In this regard, each block in the schematic flowchart diagrams and/or schematic block diagrams may represent a controller, segment, or portion of code, which comprises one or more executable instructions of the code for implementing the specified logical function(s).

It should also be noted that, in some alternative implementations, the functions noted in the block may occur out of the order noted in the Figures. For example, two blocks shown in succession may, in fact, be executed substantially concurrently, or the blocks may sometimes be executed in the reverse order, depending upon the functionality involved. Other steps and methods may be conceived that are equivalent in function, logic, or effect to one or more blocks, or portions thereof, of the illustrated Figures.

Although various arrow types and line types may be employed in the flowchart and/or block diagrams, they are understood not to limit the scope of the corresponding embodiments. Indeed, some arrows or other connectors may be used to indicate only the logical flow of the depicted embodiment. For instance, an arrow may indicate a waiting or monitoring period of unspecified duration between enumerated steps of the depicted embodiment. It will also be noted that each block of the block diagrams and/or flowchart diagrams, and combinations of blocks in the block diagrams and/or flowchart diagrams, can be implemented by special purpose hardware-based systems that perform the specified functions or acts, or combinations of special purpose hardware and code.

The description of elements in each figure may refer to elements of proceeding figures. Like numbers refer to like elements in all figures, including alternate embodiments of like elements.

As used herein, a list with a conjunction of “and/or” includes any single item in the list or a combination of items in the list. For example, a list of A, B and/or C includes only A, only B, only C, a combination of A and B, a combination of B and C, a combination of A and C or a combination of A, B and C. As used herein, a list using the terminology “one or more of” includes any single item in the list or a combination of items in the list. For example, one or more of A, B and C includes only A, only B, only C, a combination of A and B, a combination of B and C, a combination of A and C or a combination of A, B and C. As used herein, a list using the terminology “one of” includes one and only one of any single item in the list. For example, “one of A, B and C” includes only A, only B or only C and excludes combinations of A, B and C.

An apparatus with counter-flow cooling tubes includes a cooling tube configured to sit within a first portion of a slot between first and second fins of a heat sink of a computing device, where the heat sink is thermally coupled to one or more components of the computing device. The cooling tube is configured to have sides of the cooling tube contact sides of the slot. The apparatus includes one or more fans configured to direct air in a first direction through a second portion of the slot, and an air source coupled to the cooling tube configured to direct air through the cooling tube in a second direction opposite the first direction.

In some embodiments, the apparatus includes a plurality of cooling tubes, where the cooling tube is one of the plurality of cooling tubes. The slot in the heat sink includes one of a plurality of slots of the heat sink. Each of the plurality of cooling tubes is configured to fit in a first portion of a respective slot of the plurality of slots and contact both of a pair of fins of the heat sink. The air source is coupled to an input manifold that is coupled to each of the plurality of cooling tubes and that is configured to direct air in the second direction through the plurality of cooling tubes. The one or more fans are configured to direct air in the first direction in a second portion of each of the plurality of slots.

In other embodiments, the plurality of cooling tubes are connected to an output manifold on a side of the plurality of slots where air flow in the plurality of cooling tubes exit the plurality of slots, and the apparatus includes an exit tube connected to the output manifold, where the exit tube is configured to be routed out of a chassis of the computing device. In other embodiments, the air source is located exterior to a chassis of the computing device and is coupled to the input manifold via an entrance tube. In other embodiments, the air source includes a fan within a chassis of the computing device.

In some embodiments, a material of the cooling tube is configured to transfer heat from the heat sink to air passing through the cooling tube. In other embodiments, material of the cooling tube includes copper, aluminum, steel, graphite, a polymer, silicon, rubber, an elastomer and/or nylon. In other embodiments, the cooling tube is dimensioned to engage with the first and second fins with a friction fit and is configured to be repositioned within and/or removed from the slot.

In some embodiments, the apparatus includes a thermal potting cement and/or a thermal glue configured to adhere the cooling tube to the first and second fins. In other embodiments, the apparatus includes a gap pad positioned on either side of the cooling tube and contacting a side of the slot. In other embodiments, the air source is configured to produce air flow through the cooling tube having a speed that exceeds an air flow speed in the second portion of the slot due to the one or more fans. In other embodiments, the apparatus includes an air flow controller configured to adjust air flow in the cooling tube to achieve a selected temperature of the heat sink. In other embodiments, the cooling tube includes vertical side walls in contact with the sides of the slot.

An apparatus for using a computing device with counter-flow cooling tubes includes a cooling tube configured to sit within a first portion of a slot between a first electronic component and a second electronic component of a computing device. The cooling tube is configured to contact both the first and second electronic component. The apparatus includes one or more fans configured to direct air in a first direction through a second portion of the slot, and an air source coupled to the cooling tube and configured to direct air through the cooling tube in a second direction opposite the first direction.

In some embodiments, the first and second electronic components comprise two of a plurality of memory cards in memory card slots in a motherboard of the computing device. In other embodiments, the apparatus includes a plurality of cooling tubes where the cooling tube is one of a plurality of cooling tubes, and the slot between the first and second electronic components includes one of a plurality of slots between each pair of a plurality of electronic components. Each of the plurality of cooling tubes is configured to fit in a first portion of a respective slot of the plurality of slots and contact both of a pair of electronic components of the plurality of electronic components. The air source is coupled to an input manifold that is coupled to each of the plurality of cooling tubes and that is configured to direct air in the second direction through the plurality of cooling tubes. The one or more fans are configured to direct air in the first direction in a second portion of each of the plurality of slots.

In some embodiments, the apparatus includes an air flow controller configured to adjust air flow in the cooling tube to achieve a selected temperature of the first and second electronic components. In other embodiments, a material of the cooling tube is configured to transfer heat from the first and second electronic components to air passing through the cooling tube. In other embodiments, material of the cooling tube comprises copper, aluminum, steel, graphite, polymers, silicon, rubber, an elastomer and/or nylon.

A system for a computing device with counter-flow cooling tubes includes a computing device that includes a chassis, a processor in the chassis, one or more memory cards in the chassis in communication with the processor, and a cooling tube configured to fill a first portion of a slot between first and second fins of a heat sink thermally coupled to one or more components of the computing device. The processor and the one or more memory cards are included as components of the computing device. The computing device includes one or more fans configured to direct air in a first direction through a second portion of the slot. The system includes an air source coupled to the cooling tube configured to direct air through the cooling tube in a second direction opposite the first direction.

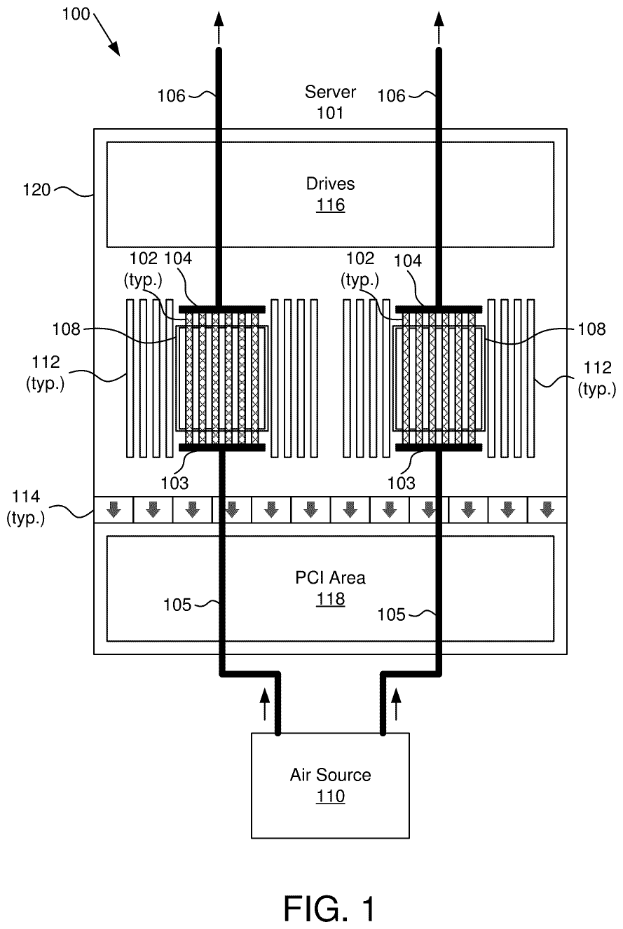

FIG. 1 is a schematic block diagram 100 illustrating a dual server 101 with heat sinks 108 over processors with counter-flow cooling tubes 102 in slots of the heat sinks 108, according to various embodiments. In some embodiments, the heat sink 108 includes a single cooling tube 102. In other embodiments, the heat sink 108 includes two or more cooling tubes 102. The dual server 101 is referred to as a computing device in the claims. In other embodiments, the computing device includes other versions of a server, such as a single server, a blade server, a rack-mounted server, a desktop computer, a laptop computer, or any other computing device that would benefit from counter-flow cooling tubes 102. In some embodiments, the heat sink 108 is for the processor under the heat sink 108. In other embodiments, the heat sink 108 is thermally coupled with another component, such as a graphic processing unit (“GPU”), an accelerator, a drive 116, or the like.

In some embodiments, the cooling tubes 102 are configured to have sides of the cooling tube 102 contact sides of the slots of the heat sink 108. In some embodiments, the cooling tubes 102 includes vertical side walls in contact with the sides of the slot. In designs with two or more cooling tubes 102, the cooling tubes 102 have a manifold 103, 104 at both ends of the cooling tubes 102. An air source 110 is connected to an input manifold 103 via an input tube 105. An output manifold 104 is connected to an exit tube 106. The exit tube 106 is configured to be routed external to a chassis housing the dual server 101.

In some embodiments, the exit tubes 106 end outside the chassis 120 of the dual server 101. In some embodiments, the two exit tubes 106 are combined into a single exit tube 106, for example, through another output manifold (not shown). In the depicted embodiments of FIG. 1, the exit tubes 106 exit on the front side of the dual servers 101. In other embodiments, the exit tubes 106 extend beyond just the front of the dual servers 101, for example, to a top of rack housing the dual servers 101. In other embodiments, the exit tubes 106 terminate at a location where there is hot air to be cooled, such as at the back of the dual servers 101. One of skill in the art will recognize other locations where the exit tubes 106 are capable of being terminated.

In the depicted embodiments, there are six cooling tubes 102 within the slots between fins of the heat sink 108. In other embodiments, there are additional cooling tubes 102 where there are additional fins of a heat sink 108. In other embodiments, there are less cooling tubes 102 than slots of the heat sink 108. In various embodiments, the cooling tubes 102 are located every other slot, every third slot, or the like. In other embodiments, the cooling tubes 102 are located in a center section of slots of the heat sink 108 with outer slots lacking a cooling tube 102. In the embodiments, the center section of the heat sink 108 is hotter than outer sections of the heat sink 108. One of skill in the art will recognize other ways to organize the cooling tubes 102 within slots of a heat sink 108 to be more efficient for a particular server 101.

In some embodiments, an air source 110 provides air to the input tubes 105 leading to the input manifold 103 and the cooling tubes 102. In the embodiments, the air source 110 is a compressor. In other embodiments, the air source 110 is a building-wide air supply system. In the embodiments, the air source 110 is capable of providing air to the cooling tubes 102 at a particular pressure and/or flow rate. In some embodiments, the air source 110 is capable of providing air at a particular temperature, which is typically lower than a temperature of heat sink 108. In other embodiments, the air source 110 is capable of providing a different amount of air to each server 101. In other embodiments, the air source 110 is capable of varying the temperature, pressure, and/or flow rate of air in the cooling tubes.

In some embodiments, the air source 110 is connected to each input tube 105 separately and is able to separately control the air flow to each input tube 105. In other embodiments, the input tubes 105 are connected to another input manifold (not shown) with a single input tube 105 running to the air source 110. In such embodiments, another variation includes the input manifold has controls to split the air at different combinations to the two input tubes 105 running to the cooling tubes 102 of each heat sink 108.

The dual servers 101 include memory cards 112 located on the sides of the processors below the heat sinks 108. In some embodiments, the memory cards 112 are dual in-line memory modules (“DIMMs”) or single in-line memory modules (“SIMMs”). In other embodiments, the memory cards 112 include volatile memory or non-volatile memory. The non-volatile memory may include flash drives or other types of non-volatile memory. In some embodiments, the memory cards 112 act as memory for the processors, for cache or the like.

In some embodiments, the dual servers 101 include one or more fans 114, which are depicted as a box with an arrow. The arrow depicts a direction of air flow through the fans 114 in a first direction. The air flow through the cooling tubes 102 is in a second direction that is opposite to the first direction, which makes the air flow through the cooling tubes 102 as a counter-flow so that the cooling tubes 102 are counter-flow cooling tubes 102. In some embodiments, air flow through the cooling tubes 102 includes a speed that exceeds air flow speed in the slot due to the one or more fans 114.

In some embodiments, one or more fans 114 direct air through a second portion of the slots in a first direction while the cooling tubes 102 are configured to fit in a first portion of a slot of the plurality of slots and the air source 110 are coupled to an input manifold 103 coupled to each of the plurality of cooling tubes 102 of each heat sink 108 and the input manifold 103 is configured to direct air in the second direction through the plurality of cooling tubes 102.

The concept of counter-flow cooling tubes 102 provides better cooling than if the air flow through the cooling tubes 102 was in the first direction, which is the same as the fans 114. A reason for this is that the heat sink 108 would typically have higher temperatures at an exit end downstream from where air enters the heat sinks 108. The counter-flow cooling tubes 102 have a coldest air interact with the heat sink 108 at the end that would be hottest due to air flow from the fans 114. In this way, the counter-flow cooling tubes 102 help to cool the heat sink 108 more efficiently than with air flow from the fans 114 only or with the cooling tubes 102 having air flow in the first direction that is the same direction as air flow from the fans 114.

The dual servers 101 also include one or more drives 116, which are memory drives for non-volatile data storage. The drives 116 are depicted at the top, front side of the servers 101, but in other embodiments are located elsewhere. The bottom area towards the back side of the servers 101 is labeled with PCI area 118, which indicates where peripheral component interface (“PCI”) cards, PCI express (“PCIe”) cards, and other communication cards are located. In some embodiments, having the communication cards at the back of the server facilitates connection along a backplane or where other cables are located. One of skill in the art will recognize other places for the PCI area 118. In some embodiments, a PCIe card or other communication card is labeled a network interface card (“NIC”). The servers 101, in various embodiments, include other components, such as buses, interfaces, a baseboard management controller (“BMC”), and the like.

In some embodiments, the dual servers 101 fit in a chassis 120, which is a container for the components of the dual server 101. In other embodiments, the chassis 120 is a durable cover for the components of the dual server 101 and the chassis 120 may include steel, aluminum, copper, or other metal. In other embodiments, the chassis 120 includes a graphite, a polycarbonate, a poly-vinyl chloride (“PVC”), or the like.

The servers 101 differ from other computing devices in that the servers 101 include counter-flow cooling tubes 102 running in slots of a heat sink 108 where the cooling tubes 102 include air flow from an air source 110 that is configured to run in a direction opposite air flow from fans 114 of the servers 101. The cooling tubes 102 run in slots of the heat sinks 108 over the processors of the server 101.

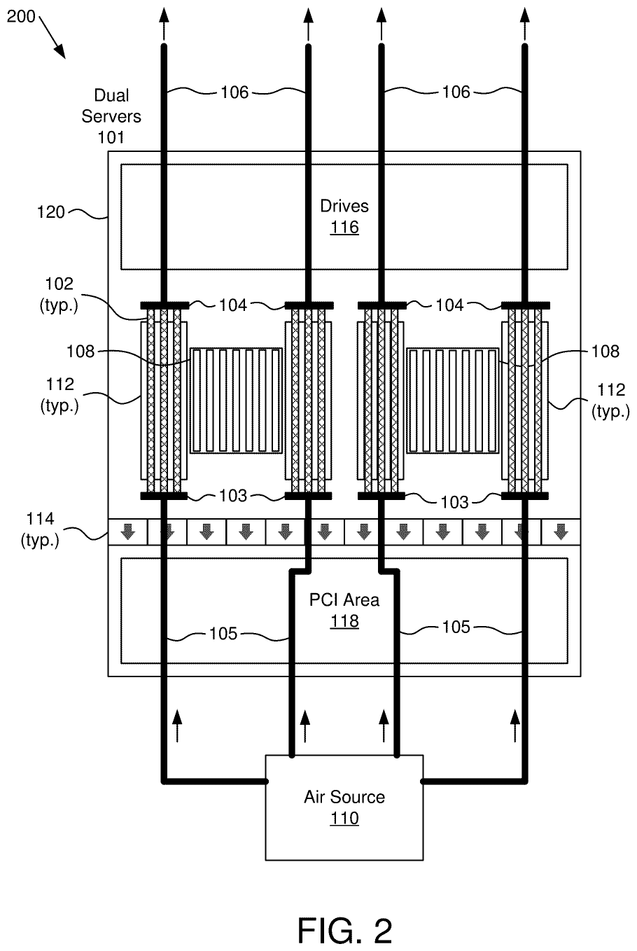

FIG. 2 is a schematic block diagram 200 illustrating a dual server 101 with counter-flow cooling tubes 102 extending through slots between memory cards 112, according to various embodiments. In various embodiments, the dual servers 101 of FIG. 2 is identical to the dual servers 101 of FIG. 1 except that the cooling tubes 102 run through the slots between the memory cards 112. The servers 101 include input manifolds 103, output manifolds 104, input tubes 105, exit tubes 106, heat sinks 108 over processors (not shown), an air source 110, heat sinks 108 over processors (not shown), an air source 110, memory cards 112, fans 114, drives 116, and a PCI area 118, which are substantially similar to the server 101 of FIG. 1.

As mentioned above, the cooling tubes 102 are running between memory cards 112 and each include an input manifold 103 and an output manifold 104. In the servers 101 depicted in FIG. 2 include cooling tubes 102 for each of the two sets of memory cards 112 so that each set of memory cards 112 include a separate input manifold 103 and output manifold 104. The exit tubes 106 are each depicted as exiting the front of the server 101 separately. In other embodiments, the exit tubes 106 include another manifold for combining the air from two output manifolds 104 of a server 101. In other embodiments, the exit tubes 106 combine into a single exit tube 106. In the embodiments, the exit tubes 106 combine into a single exit tube 106 with another exit manifold (not shown).

In some embodiments, the air flow from the air source 110 is combined into a single feed from the air source 110 (not shown) for each server 101. In some embodiments, the servers 101 include another input manifold (not shown) that expands and input tube 105 from a single input tube 105 to the two input tubes 105 using another input manifold (not shown). In further embodiments, the single input tube 105 from the air source 110 from each server 101 is used to separately control air flow to each of the server 101 separately In some embodiments, the air source 110 includes a single manifold (not shown) for all input tubes 105, which is split into the four input tubes 105. In the embodiments, the single input tube 105 split into the four input tubes 105. In related embodiments, the single input tube 105 splits into the four input tubes 105 using another input manifold (show shown). Advantageously, the embodiments of FIG. 2 provide a mechanism for extra cooling of the memory cards 112, which may be included for extra cooling for high-density and/or high-power memory cards 112, or the like.

While the embodiments of FIG. 2 depict components cooled by the counter-flow cooling tubes 102 as memory cards 112, in other embodiments, the cooling tubes 102 cool other components. The other components may include a heat sink of a graphics processing unit (“GPU”), an accelerator, drives 116, or the like. In other embodiments, the components are in parallel with a slot in between and the cooling tubes 102 fit between the parallel components.

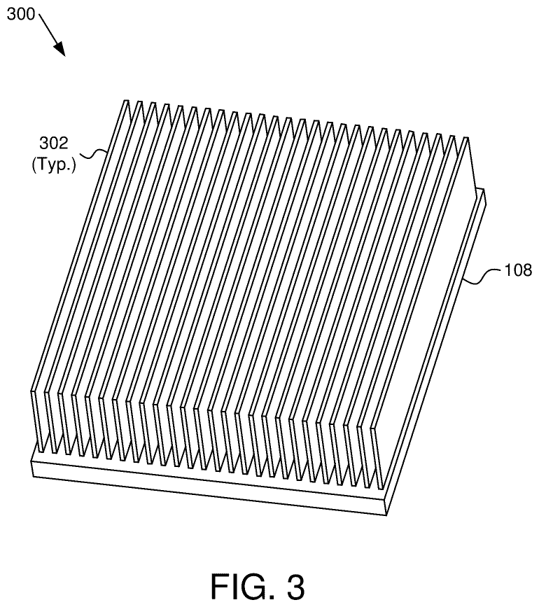

FIG. 3 is a schematic block diagram illustrating a dimensional view 300 of heat sink 108, according to various embodiments. The heat sink 108 does not include any cooling tubes 102. Typically, the heat sink 108 includes fins 302 all running in a same direction, which can facilitate the addition of cooling tubes 102.

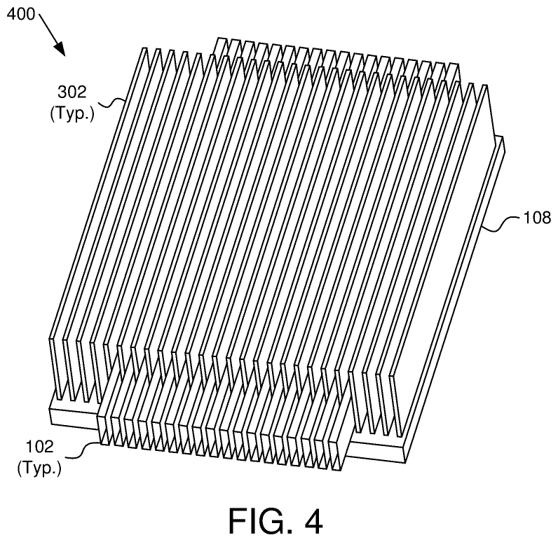

FIG. 4 is a schematic block diagram illustrating a dimensional view 400 of a heat sink 108 with counter-flow cooling tubes 102 in slots between fins 302 of the heat sink 108, according to various embodiments. The heat sink 108 is substantially similar to the heat sink 108 of FIG. 3 except for the addition of the cooling tubes 102. In the embodiments, a cross section of a cooling tube 102 is rectangular, which fits between the fins 302. In some embodiments, cooling tubes 102 fit between the fins 302 with a friction fit where the cooling tubes 102 are designed to fit between the fins 302 with the friction fit. In such an embodiment, the cooling tubes 102 may be made of a non-metallic material, such as nylon, an elastomer, a silicon, or the like. In other embodiments, the cooling tubes 102 are a metallic material, such as copper, tin, aluminum, graphite, or the like. In the embodiments, the cooling tubes 102 are cemented into place. In such embodiments, the cement includes a potting cement, a thermal glue, or the like. In some embodiments, the cooling tubes 102 include a gap pad (not shown) on one or both of the sides of the slot and the cooling tubes 102, which may allow a friction fit between the sides of the slot and the cooling tubes 102. One of skill in the art will recognize other ways for the cooling tubes 102 to be secured into slots of the heat sink or between components of a server 101.

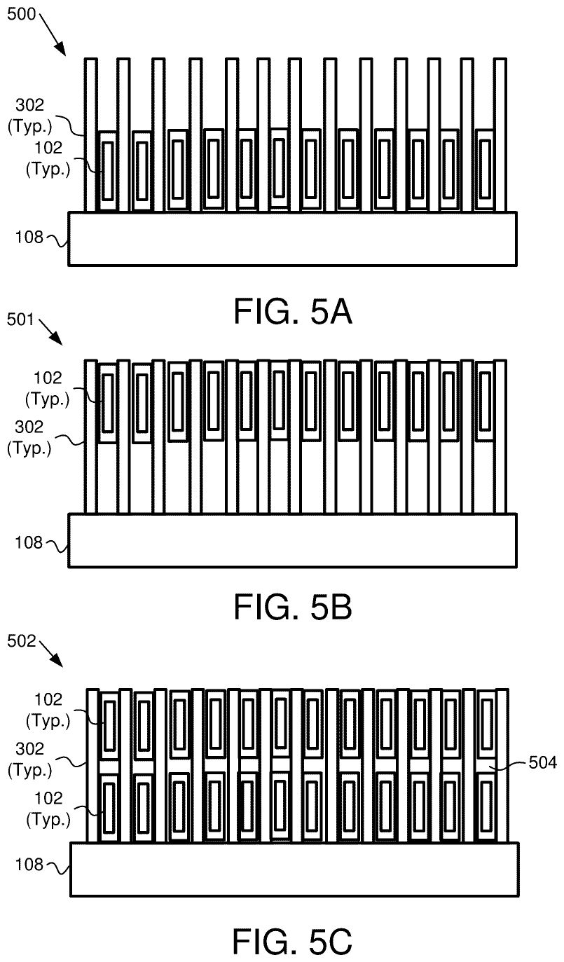

FIG. 5A is a schematic block diagram 500 illustrating a heat sink 108 with counter-flow cooling tubes 102 positioned at the bottom of slots in the heat sink 108, according to various embodiments. In the embodiments, the heat sink 108 includes cooling tubes 102 between each set of adjacent fins 302 which are located at the bottom of the slots and air flow from the fans 114 goes over the cooling tubes 102.

FIG. 5B is a schematic block diagram 501 illustrating a heat sink 108 with counter-flow cooling tubes 102 positioned at the top of slots in the heat sink 108, according to various embodiments. In the embodiments, the heat sink 108 includes cooling tubes 102 between each set of adjacent fins 302 which are located at the top of the slots and air flow from the fans 114 goes under the cooling tubes 102.

FIG. 5C is a schematic block diagram 502 illustrating a heat sink with counter-flow cooling tubes 102 positioned at the top and the bottom of slots in the heat sink 108, according to various embodiments. In the embodiments, the heat sink 108 includes cooling tubes 102 between each set of adjacent fins 302 which are located at the top and at the bottom of the slots. In the embodiments, there is an opening 504 in each slot between the top and the bottom cooling tubes 102 for air flow from the fans 114.

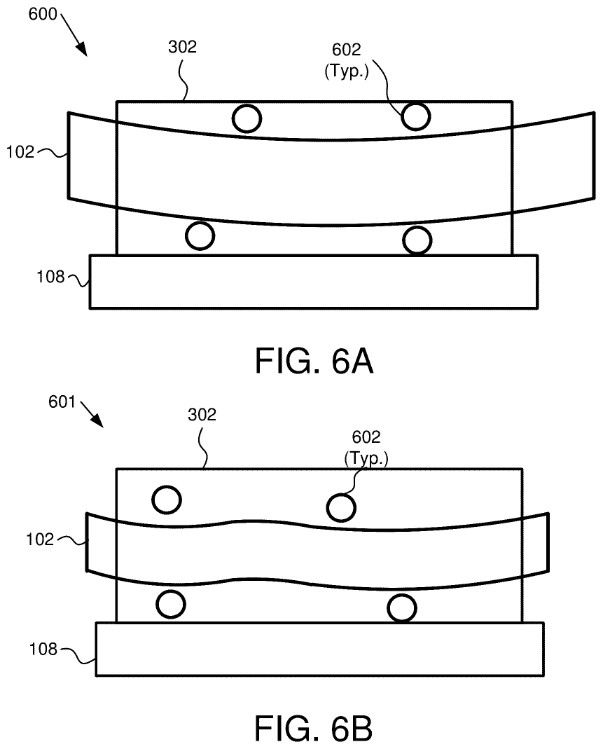

FIG. 6A is a schematic block diagram 600 illustrating a side section view of a heat sink 108 with a counter-flow cooling tube 102 curved to avoid heat pipes 602, according to various embodiments. In the embodiments, the counter-flow cooling tube 102 is flexible in a vertical direction and is able to bend around the heat pipes 602. In the embodiments, the cooling tube 102 is flexible. In some embodiments, the cooling tube 102 is non-metallic.

FIG. 6B is a schematic block diagram 601 illustrating a side section view of another heat sink 108 with a counter-flow cooling tube 102 curved to avoid heat pipes 602, according to various embodiments. In the embodiments, the counter-flow cooling tube 102 is flexible in a vertical direction and is able to have two bents around the heat pipes 602. In the embodiments, the cooling tube 102 is flexible. In some embodiments, the cooling tube 102 is non-metallic.

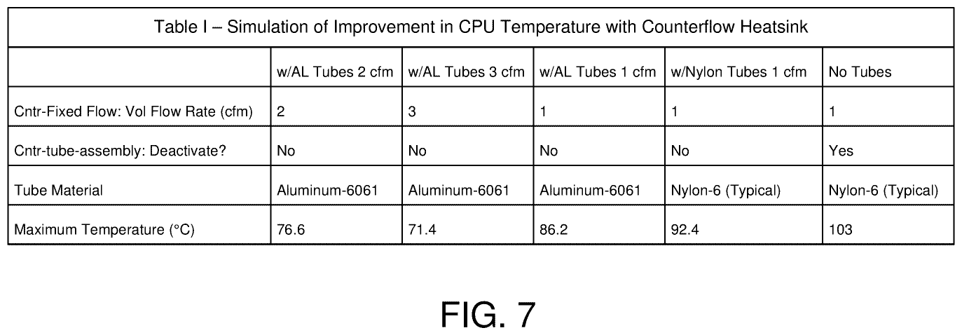

FIG. 7 is a Table I illustrating different cooling tube designs and air flow rates, according to various embodiments. Table I displays results of several simulations. The first column of Table I includes descriptions of what is in each row. The first description is “Cntr-Fixed Flow: Vol. Flow Rate (cfm), which is the flow rate of the counter-flow cooling tubes 102 and is fixed and is in units of cubic feet per minute. The next row is “Cntr-tube-assembly: Deactivate?,” which is whether or not the counter-flow cooling tubes 102 are deactivated or not. The next row is “Tube Material” so that following columns list the material of the counter-flow cooling tubes 102. The last row is “Maximum Temperature (° C.)” which is the maximum temperature of the heat sink 108 in degrees Celsius.

The second column starts with “w/AL Tubes 2 cfm,” which signifies aluminum cooling tubes 102 and a flow rate of 2 cfm. The next row of this second column is 2, which corresponds to 2 cfm, which signifies a flow rate in the cooling tubes of 2 cfm. The next row is “No,” which signifies that the cooling tube 102 is operational. The next row of the second column is “Aluminum-6061,” so that the cooling tube has a material that is aluminum 6061. The last row of the second column indicates a maximum temperature of the heat sink is 76.6° C.

The third column starts with “w/AL Tubes 3 cfm,” which signifies aluminum cooling tubes 102 and a flow rate of 3 cfm. The next row of this third column is 3, which corresponds to 3 cfm, which signifies a flow rate in the cooling tubes of 3 cfm. The next row is “No,” which signifies that the cooling tube 102 is operational. The next row of the second column is “Aluminum-6061,” so that the cooling tube has a material that is aluminum 6061. The last row of the second column indicates a maximum temperature of the heat sink is 71.4° C.

The fourth column starts with “w/AL Tubes 1 cfm,” which signifies aluminum cooling tubes 102 and a flow rate of 1 cfm. The next row of this third column is 1, which corresponds to 1 cfm, which signifies a flow rate in the cooling tubes of 1 cfm. The next row is “No,” which signifies that the cooling tube 102 is operational. The next row of the second column is “Aluminum-6061,” so that the cooling tube has a material that is aluminum 6061. The last row of the second column indicates a maximum temperature of the heat sink is 86.2° C. Note that for the same tube and different flow rates, the higher flow rates include a lower maximum temperature.

The fifth column starts with “w/Nylon Tubes 1 cfm,” which signifies Nylon cooling tubes 102 and a flow rate of 1 cfm. The next row of this third column is 1, which corresponds to 1 cfm, which signifies a flow rate in the cooling tubes of 1 cfm. The next row is “No,” which signifies that the cooling tube 102 is operational. The next row of the second column is “Nylon-6,” so that the cooling tube has a material that is Nylon-6. The last row of the second column indicates a maximum temperature of the heat sink is 92.4° C. Note that for aluminum vs nylon tubes and the same flow rates, the aluminum tubes have a lower maximum temperature.

The sixth column starts with “No Tubes” indicating that the counter-flow cooling tubes are not present. The second row is “1” as a place holder. The third column is “Yes,” indicative of the counter-flow cooling tube is deactivated and not present in the simulation. The next row is tube material and is Nylon-6, but there is no counter-flow cooling tube 102 in the simulation. The last row is the maximum temperature, which is 103° C. All of the previous columns with counter-flow cooling tubes 102 have a lower temperature.

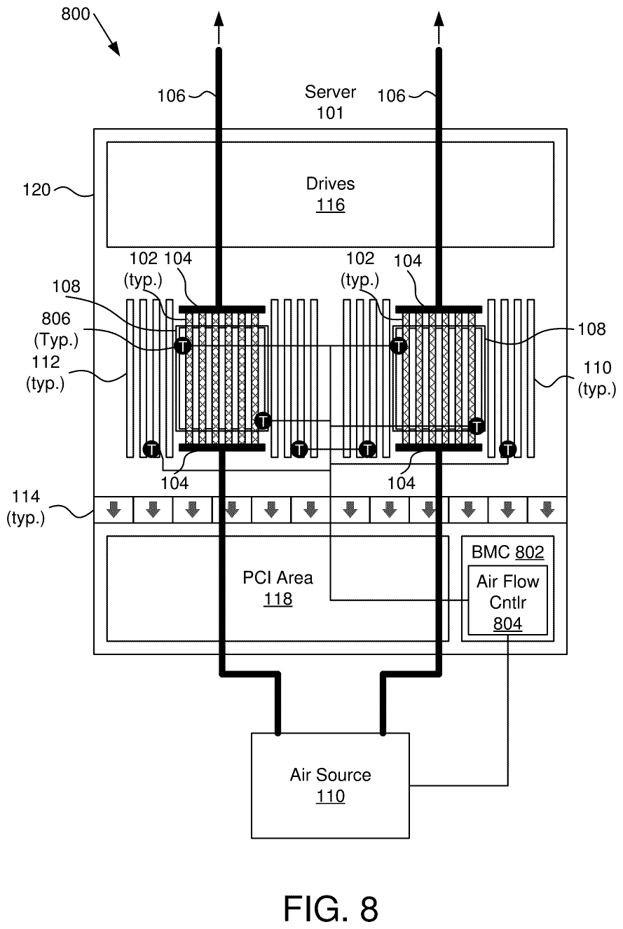

FIG. 8 is a schematic block diagram 800 illustrating a dual server 101 with heat sinks 108 over processors with counter-flow cooling tubes 102 in slots of the heat sinks 108 with temperature sensors 806 and an air flow controller 804, according to various embodiments. The dual server 101 is the same as the dual server 101 of FIG. 1 except with the addition of a baseboard management controller (“BMC”) 802, an air flow controller 804 and temperature sensors 806. The servers 101 include counter-flow cooling tubes 102, input manifolds 103, output manifolds 104, input tubes 105, exit tubes 106, heat sinks 108 over processors (not shown), an air source 110, an air source 110, memory cards 112, fans 114, drives 116, and a PCI area 118, which are substantially similar to the server 101 of FIG. 1. In the embodiments of FIG. 8, the temperature sensors 806 represent various points in the memory cards 112 and heat sinks 108 where temperatures are measured. One of skill in the art will recognize that there may be more or less temperature sensors 806 and that the temperature sensors 806 may be placed in different locations.

The air flow controller 804 is depicted in the BMC 802, but may be included in a processor or other location in the dual servers 101. The air flow controller 804, in some embodiments, is configured to adjust air flow in the cooling tubes 102 to achieve a selected temperature of a heat sink 108 or the memory cards 112 by adjusting air flow from the air source 110. In other embodiments, the air flow controller 804 adjusts an air temperature in the cooling tubes 102 to achieve a selected temperature of the heat sink 108. In other embodiments, the cooling tubes 102 are placed elsewhere and the air flow controller 804 is configured to adjust air flow from the air source 110 to adjust a temperature of other components.

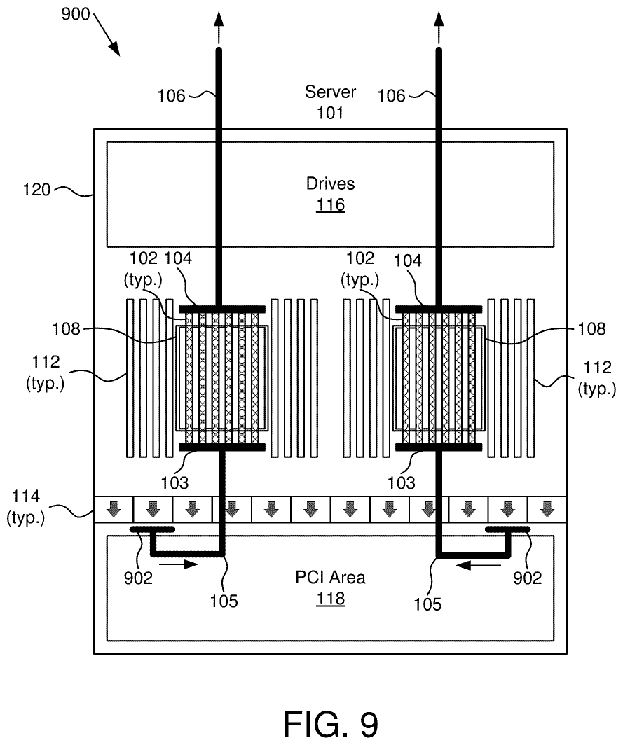

FIG. 9 is a schematic block diagram 900 illustrating a dual server 101 with heat sinks 108 over processors with counter-flow cooling tubes 102 in slots of the heat sinks 108 and fans 114 providing air for the cooling tubes 102, according to various embodiments. The dual server 101 is the same as the dual server 101 of FIG. 1 except with fans 114 providing air flow to the counter-flow cooling tubes 102. The servers 101 include counter-flow cooling tubes 102, input manifolds 103, output manifolds 104, input tubes 105, exit tubes 106, heat sinks 108 over processors (not shown), memory cards 112, fans 114, drives 116, and a PCI area 118, which are substantially similar to the server 101 of FIG. 1. In the embodiments of FIG. 9, the input tubes 105 originate at the output of a fan 114 as an air source. One of skill in the art will recognize that there may be more fans 114 providing air to the input tubes 105 and that the input to the input tubes 105 may be placed at different fans 114. At the input to the input tubes 105, there is a collector 902 shaped to collect air and to input the air to an input tube 105. The collector 902, in some embodiments is cone-shaped, funnel-shaped, or the like.

Embodiments may be practiced in other specific forms. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. An apparatus comprising:
a cooling tube configured to sit within a first portion of a slot, the slot between first and second fins of a heat sink of a computing device, the heat sink thermally coupled to one or more components of the computing device, wherein the cooling tube is configured to have sides of the cooling tube contact sides of the slot;
one or more fans configured to direct air in a first direction through a second portion of the slot; and
an air source coupled to the cooling tube configured to direct air through the cooling tube in a second direction opposite the first direction.

2. The apparatus of claim 1, further comprising a plurality of cooling tubes, wherein the cooling tube is one of the plurality of cooling tubes, and
the slot in the heat sink comprises one of a plurality of slots of the heat sink,
wherein each of the plurality of cooling tubes is configured to fit in a first portion of a respective slot of the plurality of slots and contact both of a pair of fins of the heat sink,
wherein the air source is coupled to an input manifold that is coupled to each of the plurality of cooling tubes and that is configured to direct air in the second direction through the plurality of cooling tubes, and
wherein the one or more fans are configured to direct air in the first direction in a second portion of each of the plurality of slots.

3. The apparatus of claim 2, wherein the plurality of cooling tubes are connected to an output manifold on a side of the plurality of slots where air flow in the plurality of cooling tubes exit the plurality of slots, and further comprising an exit tube connected to the output manifold, the exit tube is configured to be routed out of a chassis of the computing device.

4. The apparatus of claim 2, wherein the air source is located exterior to a chassis of the computing device and is coupled to the input manifold via an entrance tube.

5. The apparatus of claim 2, wherein the air source comprises a fan within a chassis of the computing device.

6. The apparatus of claim 1, wherein a material of the cooling tube is configured to transfer heat from the heat sink to air passing through the cooling tube.

7. The apparatus of claim 6, wherein material of the cooling tube comprises copper, aluminum, steel, graphite, polymers, silicon, rubber, an elastomer and/or nylon.

8. The apparatus of claim 1, wherein the cooling tube is dimensioned to engage with the first and second fins with a friction fit and is configured to be repositioned within and/or removed from the slot.

9. The apparatus of claim 1, further comprising a thermal potting cement and/or a thermal glue configured to adhere the cooling tube to the first and second fins.

10. The apparatus of claim 1, further comprising a gap pad positioned on either side of the cooling tube and contacting a side of the slot.

11. The apparatus of claim 1, wherein the air source is configured to produce air flow through the cooling tube having a speed that exceeds an air flow speed in the second portion of the slot caused by the one or more fans.

12. The apparatus of claim 1, further comprising an air flow controller configured to adjust air flow in the cooling tube to achieve a selected temperature of the heat sink.

13. The apparatus of claim 1, wherein the cooling tube comprises vertical side walls in contact with the sides of the slot.

14. An apparatus comprising:
a cooling tube configured to sit within a first portion of a slot between a first electronic component and a second electronic component of a computing device, wherein the cooling tube is configured to contact both the first and second electronic component;
one or more fans configured to direct air in a first direction through a second portion of the slot; and
an air source coupled to the cooling tube and configured to direct air through the cooling tube in a second direction opposite the first direction.

15. The apparatus of claim 14, wherein the first and second electronic components comprise two of a plurality of memory cards in memory card slots in a motherboard of the computing device.

16. The apparatus of claim 14, further comprising a plurality of cooling tubes, wherein the cooling tube is one of the plurality of cooling tubes, and
the slot between the first and second electronic components comprises one of a plurality of slots between electronic components,
wherein each of the plurality of cooling tubes is configured to fit in a first portion of a respective slot of the plurality of slots and contact both of a pair of electronic components of the plurality of each pair of a plurality of electronic components,
wherein the air source is coupled to an input manifold that is coupled to each of the plurality of cooling tubes and that is configured to direct air in the second direction through the plurality of cooling tubes, and
wherein the one or more fans are configured to direct air in the first direction in a second portion of each of the plurality of slots.

17. The apparatus of claim 14, further comprising an air flow controller configured to adjust air flow in the cooling tube to achieve a selected temperature of the first and second electronic components.

18. The apparatus of claim 14, wherein a material of the cooling tube is configured to transfer heat from the first and second electronic components to air passing through the cooling tube.

19. The apparatus of claim 14, wherein material of the cooling tube comprises copper, aluminum, steel, graphite, polymers, silicon, rubber, an elastomer and/or nylon.

20. A system comprising:
a computing device comprising:
a chassis;
a processor in the chassis;
one or more memory cards in the chassis in communication with the processor;
a cooling tube configured to fill a first portion of a slot between first and second fins of a heat sink thermally coupled to one or more components of the computing device, wherein the processor and the one or more memory cards comprise components of the computing device; and
one or more fans configured to direct air in a first direction through a second portion of the slot; and
an air source coupled to the cooling tube configured to direct air through the cooling tube in a second direction opposite the first direction.
